(19) United States
(12) Patent Application Publication
(10) Pub. No.: US 2013/0015356 A1
(43) Pub. Date: Jan. 17, 2013

(54) Reflection Sensing System

(71) Applicants: Cheng-Chung Shih, Fremont, CA (US); Yung-Chuan Chuang, Taipei City (TW); Chien-Chung Hsiao, Taoyuan City (TW)

(72) Inventors: Cheng-Chung Shih, Fremont, CA (US); Yung-Chuan Chuang, Taipei City (TW); Chien-Chung Hsiao, Taoyuan City (TW)

(73) Assignee: CAPELLA MICROSYSTEMS (TAIWAN), INC., New Taipei City (TW)

(21) Appl. No.: 13/325,857

(22) Filed: Dec. 14, 2011

Related U.S. Application Data
(60) Provisional application No. 61/506,173, filed on Jul. 11, 2011.

(51) Int. Cl. H01L 31/167; G01J 5/08; G01J 1/44

(52) U.S. Cl. 250/353; 250/214.1; 250/393

(57) ABSTRACT

A reflection sensing system comprising a body, an illuming module and a detecting module. The body is made of LCP. The illuming module includes a first accommodating space and an LED, and the detecting module includes a light detector. The first accommodating space is disposed in the body and has a first opening at one end. In the first accommodating space, the neighboring region relative to the first opening is parabolic or approximately parabolic. At an end at an inner side of the first accommodating space near the light detector, at least one cross-section near the first opening is not parabolic or approximately parabolic. The LED is disposed at the focus of the first accommodating space and aligned towards the first opening. The light detector of the detecting module is disposed in the body and generates a sensing signal after receiving light.

### CROSS-REFERENCE TO RELATED APPLICATION

This application claims the benefit of provisional U.S. patent application Ser. No. 61/506,173, filed on Jul. 11, 2011, in the United States Patent and Trademark Office, the disclosure of which is incorporated herein in its entirety by reference.

### BACKGROUND OF THE INVENTION

1. Field of the Invention

The present invention relates to a reflection sensing system, in particular to the reflection sensing system made of a liquid crystal polymer (LCP), and capable of manufacturing an integrally formed casing with a light condensation effect by using a modular molding method.

2. Description of the Related Art

Proximity sensor is a reflection sensing system having a light detector for receiving a light emitted from the light emitting diode (LED) and reflected from an object to generate a sensing signal correspondingly. The proximity sensor can be used extensively in different electronic products such as mobile phones and notebook computers.

With reference to FIG. 1 for a top view of a conventional reflection sensing system, the conventional reflection sensing system has to manufacture a main body 10 and cover 13 separately in order to reduce the production of noises. A first hole 130 of the cover 13 must be smaller than a first opening 112 formed at a first accommodating space of a LED. Similarly, a second hole 131 of the cover 13 must be smaller than a second opening 122 formed at the second accommodating space disposed with the light detector. Therefore, the manufacturing process of the proximity sensors requires assembling the main body 10 and the cover 13 of the reflection sensing system together.

In the aforementioned method of producing the reflection sensing system, the noises can be reduced effectively, but the method also incurs a higher cost for producing the main body 10 and the cover 13, and raises many technical problems in the process of assembling the main body 10 and the cover 13. Therefore it is a main subject for the present invention to design a proximity sensor capable of reducing noises effectively without a need of manufacturing the main body 10 and the cover 13 separately or having technical problems of assembling the main body 10 and the cover 13.

### SUMMARY OF THE INVENTION

In view of the aforementioned problem, it is a primary objective of the present invention to provide a reflection sensing system to overcome the problems of the conventional reflection sensing system that requires manufacturing the main body and the cover separately and has technical problems in the assembling process.

To achieve the foregoing objective, the present invention provides a reflection sensing system, comprising: a main body, having a plurality of electric contacts formed thereon; an illuming module, comprising: a first accommodating space, formed in the main body, and having a first opening formed at an end of the first accommodating space, and a cross-section of the neighboring region relative to the first opening in the first accommodating space being in a parabolic shape or similar to a parabolic shape; and a light emitting diode (LED), installed in the first accommodating space and electrically coupled to the plurality of electric contacts, and the LED being installed at a focus on the parabolic cross-section of the first accommodating space and aligned towards the first opening; and a detecting module, comprising: a light detector, installed on the main body, and coupled to the plurality of electric contacts, for providing a sensing signal after receiving a light; wherein, an end at an inner side of the first accommodating space close to the light detector, at least one cross-section close to the first opening is not in a parabolic shape or similar to the parabolic shape.

Wherein, the end at the inner side of the first accommodating space close to the light detector is a vertical plane or similar to the vertical plane close to the first opening.

Wherein, the detecting module further comprises a second accommodating space surrounding the light detector and installed on the main body, and a second opening formed at an end of the second accommodating space with that the second opening is smaller than the second accommodating space.

Wherein, the first opening is greater than or equal to the first accommodating space.

Wherein, the main body is made of a high-temperature resistant material, and the high-temperature resistant material includes a liquid crystal polymer (LCP).

Wherein, inner surfaces of the first accommodating space, the second accommodating space or both are self-reflective or coated with a reflective material for reflecting a light.

Wherein, the reflective material can be silver, gold, aluminum or any other reflective material.

Wherein, an included angle between the tangent at a wall of the first accommodating space and the bottom of the main body falls within a range of 20-80 degrees.

Wherein, an included angle between the tangent at a wall of the first accommodating space and the bottom of the main body falls within a range of 40-60 degrees.

Wherein, the LED emits invisible light.

Wherein, the LED emits infrared light.

Wherein, the LED emits visible light.

In summation, the reflection sensing system of the present invention has one or more of the following advantages:

(1) The reflection sensing system comes with accommodating spaces in special design and shape to achieve the effect of reducing noises.

(2) The reflection sensing system can integrally form the casing with the light condensation effect by using a modular molding method to lower the manufacturing cost effectively.

(3) In the manufacturing process of the reflection sensing system, it is not necessary to assemble the main body and the cover together, and thus reducing the technical problems occurred in the assembling process.

### BRIEF DESCRIPTION OF THE DRAWINGS

FIG. 1 is a top view of a conventional reflection sensing system;

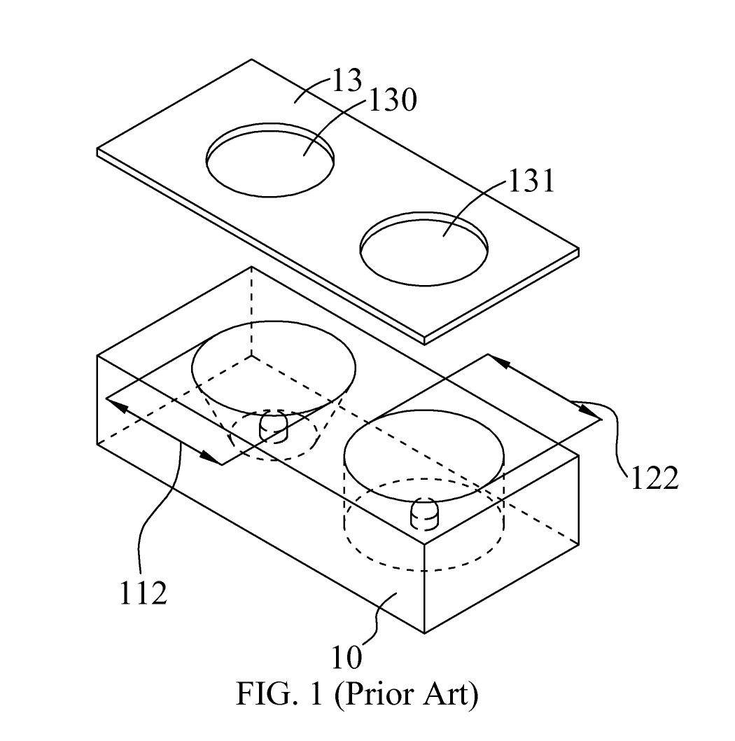

FIG. 2 is a top view of a reflection sensing system in accordance with a first preferred embodiment of the present invention;

FIG. 3 is a cross-sectional view of an illuming module of a reflection sensing system in accordance with a first preferred embodiment of the present invention;

FIG. 4 is a cross-sectional view of a detecting module of a reflection sensing system in accordance with a first preferred embodiment of the present invention; and

FIG. 5 is a schematic view of a reflection sensing system in accordance with a first preferred embodiment of the present invention.

### DETAILED DESCRIPTION OF THE PREFERRED EMBODIMENTS

The technical characteristics of the present invention will become apparent with the detailed description of the preferred embodiments accompanied with the illustration of related drawings as follows. It is noteworthy to point out that same numerals are used for representing respective elements for the description of a preferred embodiment and the illustration of related drawings.

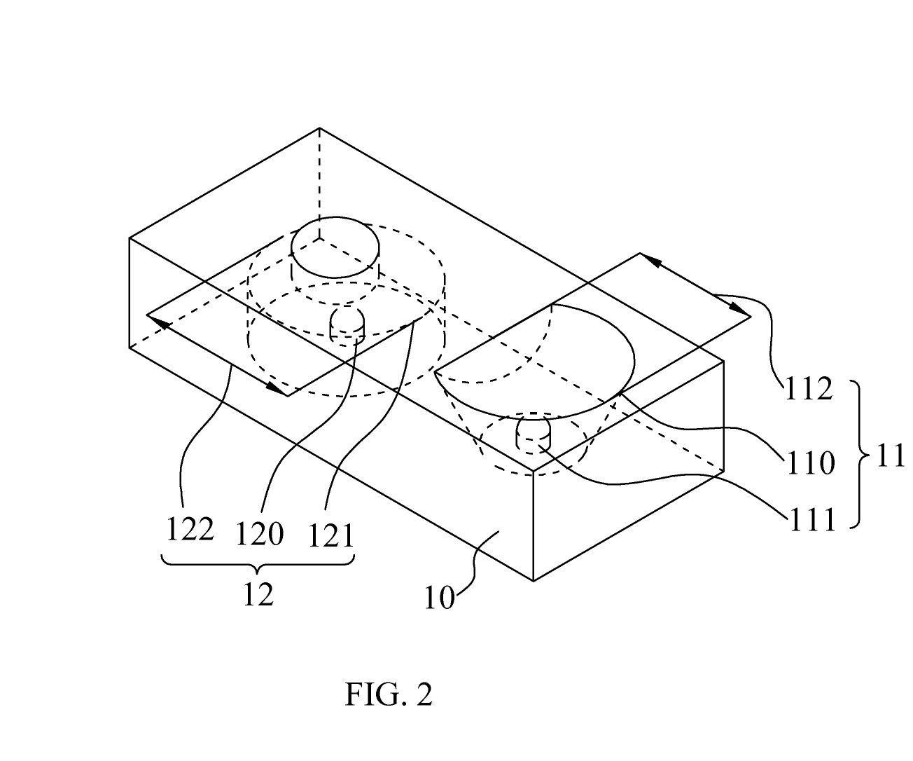

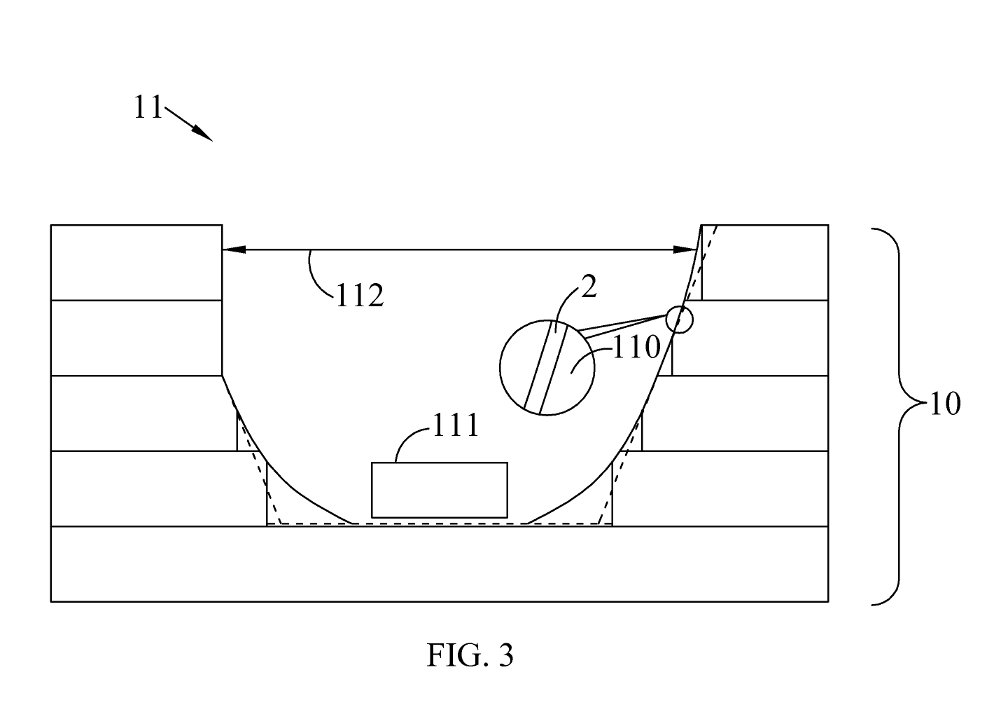

With reference to FIG. 2 for a top view of a reflection sensing system in accordance with a first preferred embodiment of the present invention, the reflection sensing system comprises a main body 10, an illuming module 11 and a detecting module 12. Wherein, the main body 10 is made of a liquid crystal polymer (LCP) or any other colloid with plasticity, and a plurality of electric contacts are disposed on the main body 10 (not shown in the figure). The illuming module 11 comprises a first accommodating space 110 and a light emitting diode (LED) 111, and the detecting module 12 comprises a light detector 120. The first accommodating space 110 is disposed in the main body 10 and has a first opening 112 formed at an end of the first accommodating space 110, and a cross-section of the first accommodating space 110 is in a parabolic shape or similar to the parabolic shape or preferably a straight line similar to parabolic shape (as shown in FIG. 3).

Wherein, an end at an inner side of the first accommodating space 110 close to the light detector 120, a vertical plane is formed near the first opening 112. Such design can elongate the distance between the illuming module 11 and the detecting module 12, and reduce the interference imposed on the light detector and caused by a lateral scattering light from the LED 111 through a transparent glass or acrylic casing, so as to improve the accuracy of the reflection sensing system. The LED 111 is installed in the first accommodating space 110 and electrically coupled to electric contacts (not shown in the figure), and the LED 111 is installed in at a focus on a parabolic cross-section of the first accommodating space 110 and aligned towards the first opening 112 (as shown in FIG. 3).

In addition, the light detector 120 of the detecting module 12 is installed on the main body 10 and electrically coupled to electric contacts (not shown in the figure) for generating a sensing signal after receiving light correspondingly, and the light detector 120 is installed on the same main body 10 with the illuming module 11. Wherein, the detecting module 12 further comprises a second accommodating space 121 surrounding the light detector 120 and disposed on the main body 10, and a second opening 122 is formed at an end of the second accommodating space 121. The second opening 122 is smaller than the second accommodating space 121 to prevent the production of noises.

The intensity of the noises is related to the size of the first opening 112 and the second opening 122, and the distance therebetween. The light detector 120 is installed in the second accommodating space 121 and aligned towards the second opening 122. Wherein, the LED 111 and the light detector 120 may be coupled to each other through the connection of electric contacts (not shown in the figure) for a control of transmitting signals to the outside or receiving external signals.

It is noteworthy to point out that the first accommodating space 110 of the present invention is designed with a special shape, so that the main body 10 can be integrally formed by using a modular molding method without manufacturing the cover and the main body 10 separately to achieve the effect of reducing the noises. Since the reflection sensing system of the present invention no longer needs to manufacture the cover and the main body 10 separately, so that the reflection sensing system of the present invention can be manufactured with a lower manufacturing cost. In addition, the reflection sensing system of the present invention can avoid the technical problems occurred in the conventional method of assembling the cover and the main body.

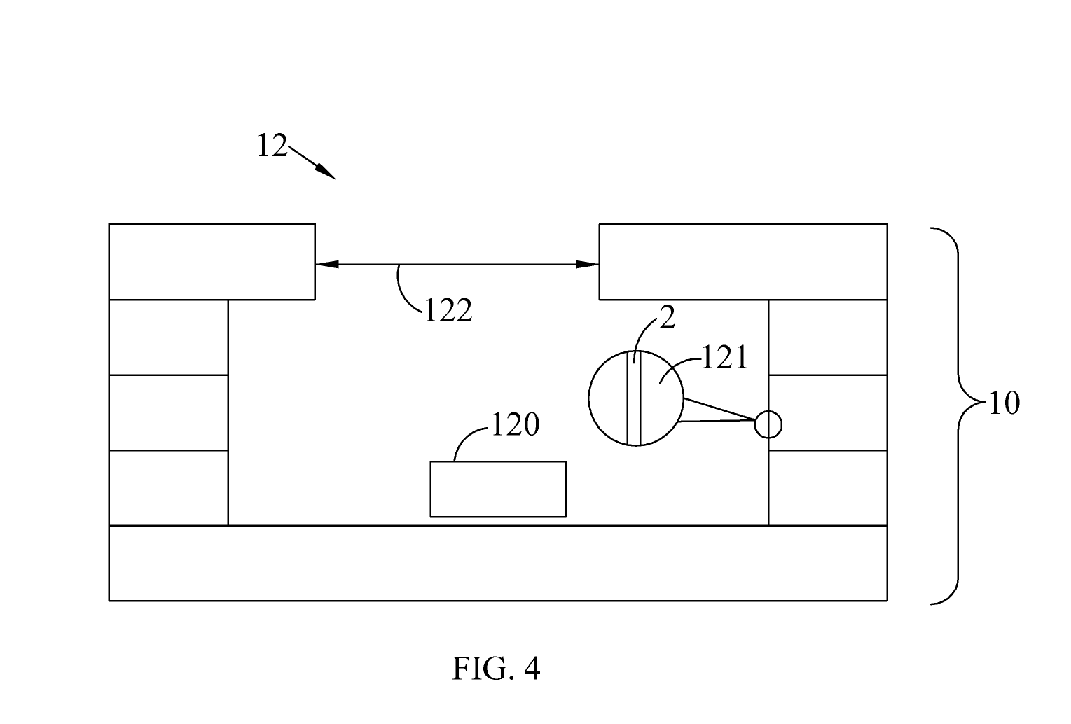

With reference to FIGS. 3 and 4 for cross-sectional views of an illuming module and a detecting module of a reflection sensing system in accordance with a first preferred embodiment of the present invention respectively, inner surfaces of the first accommodating space 110, the second accommodating space 121 or both are self-reflective or coated with a reflective material 2 to reflect light. In a preferred embodiment, the reflective material 2 can be silver, gold or aluminum. In addition, an included angle between the tangent at a wall of the first accommodating space 110 and the bottom of the main body 10 falls preferably within a range of 20˜80 degrees or more preferably within 40˜60 degrees.

In FIG. 4, the second opening 122 of the second accommodating space 121 is designed with a size smaller than the second accommodating space 121 to avoid the production of noises. To adopt the modular molding method for the integral formation of the main body 10, the first accommodating space 110 cannot be the same design with the second accommodating space 21.

However, the reflection sensing system installed in an electronic device is often interfered to generate noises. For example, if the reflection sensing system is installed in a mobile phone, most of the lights emitted from the LED 111 pass through a transparent glass of the mobile phone and projects onto an object. However, there is still a small portion of the light is reflected from the transparent glass to interfere with the light detector 120, and thus noises are produced to affect the accuracy of the reflection sensing system.

Therefore, the reflection sensing system of the present invention has a first accommodating space 100 with a different design and a different shape comparing to the prior art as shown in FIG. 3. The cross-section of the neighboring region relative to the first opening in first accommodating space is in a parabolic shape or similar to a parabolic shape. An end of an inner side of the first accommodating space 110 close to the light detector 120, at least one cross-section near the first opening 112 is not in a parabolic shape or similar to the parabolic shape, in order to reduce the noises caused by the light exited from the illuming module 11. In this preferred embodiment, the end at an inner side of the first accommodating space 110 close to the light detector 120, a vertical plane or similar to the vertical plane is formed near the first opening 112. Such design not only reduces the interference imposed on the light detector 120 and caused by a lateral scattering light from the LED 111 through a surface of a transparent glass or acrylic casing, but also integrally forms the main body of the reflection sensing system of the present invention by using the modular molding method. Of course, the aforementioned method is a preferred embodiment used for illustrating the present invention only, but not intended for limiting the scope of the invention. For example, the position of the vertical plane or the similar vertical plane can be different from the position as shown in FIG. 3.

However, in a practical application, if the surfaces of the first accommodating space 110 and the second accommodating space 121 are coated with a metal reflective material such as silver, gold or aluminum, the metal reflective material will efficiently block light from passing through the main body 10 made of LCP to the light detector 120 of the second accommodating space 121, in order to reduce the interference significantly and provide a better accuracy of the reflection sensing system.

If a white LCP is used for making the main body 10, the white LCP has the self-reflective feature, so that it is not necessary to coat the metal reflective material onto the surfaces of the first accommodating space 110 and the second accommodating space 121. Thus, light may pass through the main body 10 made of LCP to the light detector 120 of the second accommodating space 121 easily and noises will be produced. To avoid the aforementioned situation, a front side of the main body 10 made of LCP is usually coated with a black dye to reduce or eliminate the generation of the interference and provide a more accurate reflective-light sensor.

However, in practical applications, the metal reflective material may give a better effect due to the better reflectivity of the metal reflective material, while blocking the light from passing through the main body made of LCP, so as to reduce the production of noises.

Of course, the shapes of the first accommodating space 110 and the second accommodating space 121 are not limited to those shown in the figure, but they can be changed freely according to the actual needs.

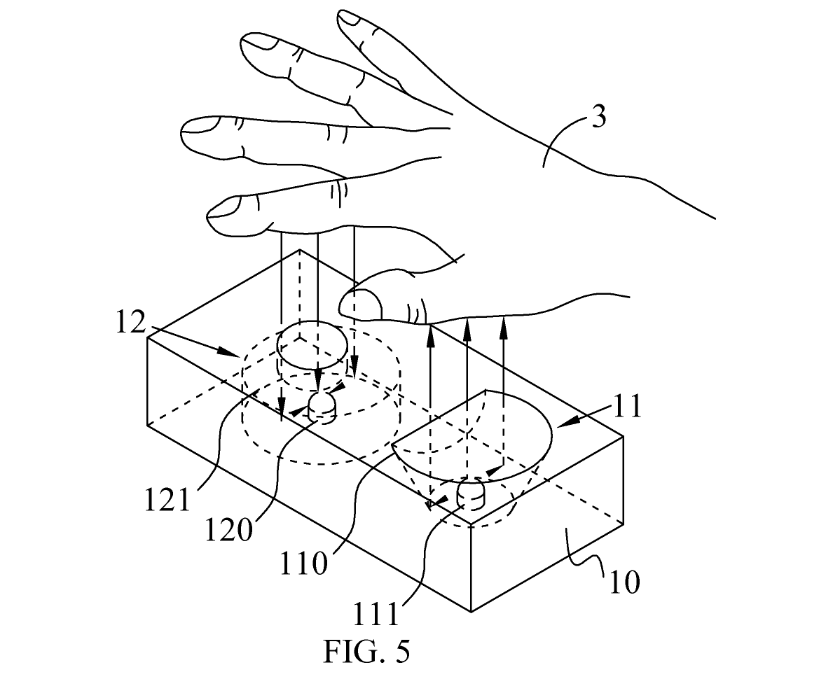

With reference to FIG. 5 for a schematic view of a reflection sensing system in accordance with a first preferred embodiment of the present invention, the LED 111 emits invisible light, preferably infrared light. The light emitted from the LED 111 disposed at a focus in the first accommodating space 110 is collected on the wall with a parabolic cross-section from different directions and then exited in parallel. When an object 3 is situated close to this reflection sensing system, the parallel-exited light is reflected to the detecting module 12, and the detecting module 12 collects the reflected light through the second accommodating space 121 to the light detector 120. Now, the light detector 120 generates a sensing signal according to a detected light, and transmits the sensing signals through the electrically-coupled electric contact (not shown in the figure).

In addition, a reflection sensing system in accordance with another preferred embodiment of the present invention may be formed by a different LED 111 and a different light detector 120, such as a combination of a white light LED and a RGB sensor. Therefore, the reflection sensing system of the present invention can be applied for paper color detection.

The reflection sensing system of the present invention enhance the intensity of the light projected onto the object through installing the LED at a focus on the similarly parabolic shaped cross-section of the first accommodating space, so that the light intensity reflected from the object can be more and more easily detected. With an asymmetric design and shape of the first accommodating space, the interference of the lateral scatters of the light emitted from the LED through a surface of the transparent glass or acrylic casing to the light detector may be reduced significantly and the main body of the reflection sensing system can be integrally formed by the modular molding method to lower the cost and eliminate technical problems during the production. In addition, the light detector is installed in the second accommodating space to enhance the intensity of the light detected by the light detector in the reflection sensing system of the present invention, so as to solve the problems of the low sensitivity of the light detector or misjudgments. Obviously, the reflection sensing system of the present invention can indeed overcome the shortcomings of the prior art efficiently.

While the invention has been described by means of specific embodiments, numerous modifications and variations could be made thereto by those skilled in the art without departing from the scope and spirit of the invention set forth in the claims.

What is claimed is:

1. A reflection sensing system, comprising:
a main body, having a plurality of electric contacts formed thereon;
an illuming module, comprising:
a first accommodating space, formed in the main body, and having a first opening formed at an end of the first accommodating space, and a cross-section of the neighboring region relative to the first opening in the first accommodating space being in a parabolic shape or similar to the parabolic shape; and
a light emitting diode (LED), installed in the first accommodating space and electrically coupled to the plurality of electric contacts, and the LED being installed at a focus on the parabolic cross-section of the first accommodating space and aligned towards the first opening; and
a detecting module, comprising:
a light detector, installed on the main body, and coupled to the plurality of electric contacts, for providing a sensing signal after receiving light;
wherein, an end at an inner side of the first accommodating space close to the light detector, at least one cross-section close to the first opening is not in a parabolic shape or similar to the parabolic shape.

2. The reflection sensing system of claim 1, wherein the end at the inner side of the first accommodating space close to the light detector being a vertical plane or similar to the vertical plane near the first opening.

3. The reflection sensing system of claim 1, wherein the detecting module further comprises a second accommodating space surrounding the light detector and installed on the main body, and a second opening formed at an end of the second accommodating space with that the second opening is smaller than the second accommodating space.

4. The reflection sensing system of claim 3, wherein inner surfaces of the first accommodating space, the second accommodating space or both are self-reflective or coated with a reflective material for reflecting light.

5. The reflection sensing system of claim 4, wherein the reflective material is silver, gold or aluminum.

6. The reflection sensing system of claim 3, wherein an included angle between the tangent at a wall of the first accommodating space and a bottom of the main body falls within a range of 20˜80 degrees.

7. The reflection sensing system of claim 6, wherein an included angle between the tangent at the wall of the first accommodating space and the bottom of the main body falls within a range of 40˜60 degrees.

8. The reflection sensing system of claim 1, wherein the first opening is greater than or equal to the first accommodating space.

9. The reflection sensing system of claim 1, wherein the main body is made of a high-temperature resistant material, and the high-temperature resistant material includes a liquid crystal polymer (LCP).

10. The reflection sensing system of claim 1, wherein the LED emits invisible light.

11. The reflection sensing system of claim 10, wherein the LED emits infrared light.

12. The reflection sensing system of claim 1, wherein the LED emits visible light.
